(19) United States
(12) Patent Application Publication
(10) Pub. No.: US 2009/0168357 A1
(43) Pub. Date: Jul. 2, 2009

(54) PLASMA DISPLAY APPARATUS

(75) Inventors: Kuninori Suzuki, Chigasaki (JP); Hideaki Ohki, Ota (JP); Shinji Komaba, Fujisawa (JP)

Correspondence Address: MCDERMOTT WILL & EMERY LLP, 600 13TH STREET, N.W., WASHINGTON, DC, 20005-3096, US

(73) Assignee: HITACHI, LTD

(21) Appl. No.: 12/182,911

(22) Filed: Jul. 30, 2008

(30) Foreign Application Priority Data
Dec. 27, 2007 (JP) 2007-338007

(51) Int. Cl. H05K 7/20; G06F 1/16

(52) U.S. Cl. 361/709

(57) ABSTRACT

A plasma display apparatus includes a plasma display panel, a chassis having the plasma display panel fixedly mounted on one face thereof, and having reinforcing members disposed as bulges on another face thereof to extend alongside each other, a heat sink fixedly mounted on the reinforcing members extending alongside each other to bridge between the reinforcing members, and a circuit board fixedly mounted on the heat sink to drive the plasma display panel.

### BACKGROUND OF THE INVENTION

1. Field of the Invention

The disclosures herein generally relate to plasma display apparatuses, and particularly relate to a plasma display apparatus having a chassis to which a plasma display panel is fixedly mounted.

2. Description of the Related Art

A plasma display apparatus having a certain plasma display panel module configuration has been in existence for some years. In this plasma display panel module configuration, a plasma display panel is fixedly attached to a front face of a chassis through an adhesive layer such as a double-faced adhesive tape, and, also, a circuit board for drive circuits, power-supply circuits, and control circuits necessary to drive the plasma display panel is fixedly mounted to a back face of the chassis. In such plasma display apparatus, a heat sink having a fin-like shape is disposed on the circuit board for the purpose of dissipating heat from the circuit boards.

FIG. 10 is a cross-sectional view of a plasma display panel module of a related-art plasma display apparatus. As shown in FIG. 10, a plasma display panel 10 is fixedly attached to a front face (i.e., face on the right-hand side in the view shown in FIG. 10) of a chassis 130 through an adhesive layer 80 such as a double-faced adhesive tape. A circuit board 160 is fixedly mounted to a back face (i.e., face on the left-hand side in the view shown in FIG. 10) of the chassis 130 by use of screws 175 and bosses 140. The circuit board 160 generates a large amount of heat. In order to dissipate the heat effectively, a heat sink 150 is disposed on the circuit board 160, and a heat source device 170 such as an FET (field-effect transistor) or the like on the circuit board 160 is fixed to the fin-like-shape heat sink 150 by use of a screw 177 to help dissipate the heat.

Another example of a display apparatus having a heat dissipation structure is disclosed in Japanese Patent Application Publication No. 2007-155808. In this display apparatus having a display panel assembled with a case, a reinforcement supporting member for the display panel fixedly mounted to the case is positioned to be in direct contact with heat source components generating heat inside the case, so that the reinforcement supporting member also serves as a heat sink for dissipating heat from the heat generating components. This arrangement is aimed at preventing an increase in the number of components associated with the provision of a heat sink thereby to prevent an increase in manufacturing cost.

In the related-art configuration shown in FIG. 10, however, a heat dissipating surface of the heat sink 150 extends in a thickness direction of the plasma display panel 10, which gives rise to a problem in that the plasma display apparatus becomes thicker. Further, when the chassis 130 supports the circuit board 160 on which a heavy object such as the fin-like-shape heat sink 150 is mounted, a distortion of the circuit board 160 propagates as a stress to the plasma display panel 10 through the chassis 130. This gives rise to a problem that the plasma display panel 10 may suffer a defect (e.g., crack).

The configuration described in the above-noted patent document can help to dissipate heat while reducing the number of components. Since the circuit board is directly mounted to the back face of the display panel, however, a distortion of the circuit board serves to apply an undesirable stress to the display panel. Also, no chassis is used to fix the circuit board in this configuration. This gives rise to a problem that the mounting of the circuit board is not sufficiently secure.

Accordingly, it is desirable to provide a plasma display apparatus that can increase the efficiency of head dissipation of the circuit board while using a thin plasma display panel module, and that can also reduce a stress applied to the plasma display panel.

### SUMMARY OF THE INVENTION

It is a general object of the present invention to provide a plasma display apparatus that substantially obviates one or more problems caused by the limitations and disadvantages of the related art.

In order to achieve the object, a plasma display apparatus of the first aspect includes:

a plasma display panel;

a chassis having the plasma display panel fixedly mounted on one face thereof, and having reinforcing members disposed as bulges on another face thereof to extend alongside each other;

a heat sink fixedly mounted on the reinforcing members extending alongside each other to bridge between the reinforcing members; and

a circuit board fixedly mounted on the heat sink to drive the plasma display panel.

This arrangement can hold the circuit board in such a position that it has no contact with the chassis, thereby preventing a stress from being transmitted to the plasma display panel. Further, since the heat sink is provided to bridge between the reinforcing members on the back face of the chassis, a large heat dissipation area can be secured, thereby increasing heat dissipation efficiency.

The plasma display apparatus of the second aspect is configured based on the plasma display apparatus of the first aspect, such that the circuit board is situated between the heat sink and the chassis.

With this arrangement, the plasma display panel module can be implemented as a thin module, and can be configured such that a stress is not transmitted from the circuit board to the plasma display panel.

The plasma display apparatus of the third aspect is configured based on the plasma display apparatus of the first or second aspect, such that the heat sink is a flat heat dissipating plate.

With this arrangement, the heat sink is implemented by use of a simple configuration, which can support the circuit board with sufficient fixing strength, and the thickness of the plasma display panel module can be set to a minimum necessary thickness.

The plasma display apparatus of the fourth aspect is configured based on the plasma display apparatus of one of the first through third aspects, such that the reinforcing members are reinforcing metal parts each having a flat face at an elevated top.

With this provision, the chassis can be reinforced by use of a simple member and configuration. Further, a sufficient contact area is secured between the reinforcing members and the heat sink so as to ensure the reliable fixing of the heat sink to the reinforcing members.

The plasma display apparatus of the fifth aspect is configured based on the plasma display apparatus of one of the first through fourth aspects, such that the heat sink has cooling fins provided on a surface thereof.

This configuration can further increase the efficiency of heat dissipation from the heat sink.

The plasma display apparatus of the sixth aspect is configured based on the plasma display apparatus of one of the third through fifth aspects, such that a rear cover configured to cover said another face of the chassis, and a thermal conduction sheet placed between the rear cover and the heat sink.

This configuration allows the heat transmitted to the heat sink to be transmitted to outside the case through the thermal conduction sheet, thereby further increasing the efficiency of heat dissipation of the plasma display apparatus.

The plasma display apparatus of the seventh aspect is configured based on the plasma display apparatus of one of the first through sixth aspects, such that the circuit board has a heat source device mounted thereon, which is fixedly attached to the heat sink.

This arrangement can transmit the heat generated by the heat source device mounted on the circuit board to the heat sink, thereby helping to dissipate heat from the heat source device.

The plasma display apparatus of the eighth aspect is configured based on the plasma display apparatus of the seventh aspect, such that the heat source device has a lead that is bent, the heat source device being laid in horizontal position to be fixedly attached to the heat sink.

This arrangement can secure a sufficient heat dissipation area in the horizontal direction of the plasma display panel, which makes it possible for the plasma display panel module to be implemented as a thin module while increasing the heat dissipation efficiency.

The plasma display apparatus of the ninth aspect is configured based on the plasma display apparatus of the eighth aspect, such that the heat source device is a field effect transistor.

With this arrangement, heat dissipation efficiency can be improved for field effect transistors, which are provided in large quantity on the circuit board and generate a large amount of heat.

The plasma display apparatus of the tenth aspect is configured based on the plasma display apparatus of one of the first through ninth aspects, such that the circuit board includes at least one of an X drive circuit board and a Y drive circuit board.

With this arrangement, a thin panel configuration can hold the drive circuit boards that generate a large amount of heat, while preventing a stress from being applied to the plasma display panel.

The plasma display apparatus of the eleventh aspect is configured based on the plasma display apparatus of one of the first through tenth aspects, such that the circuit board includes a power-supply circuit board.

With this arrangement, a thin panel configuration can hold the power-supply circuit board that generates a large amount of heat, while preventing a stress from being applied to the plasma display panel.

According to at least one embodiment of the present invention, a thin plasma display apparatus that has high heat dissipation efficiency can be implemented while eliminating a risk of applying a stress to the plasma display panel.

### BRIEF DESCRIPTION OF THE DRAWINGS

Other objects and further features of the present invention will be apparent from the following detailed description when read in conjunction with the accompanying drawings, in which:

FIG. 1 is a drawing showing a schematic configuration of the entirety of a plasma display panel module of a plasma display apparatus according to a first embodiment;

FIG. 2 is a drawing showing an example of the configuration of the plasma display panel of the plasma display apparatus according to the first embodiment;

FIG. 3 is a perspective view showing the entirety of the plasma display panel module of the plasma display apparatus according to the first embodiment;

FIG. 4 is an exploded, perspective view of the entirety of the plasma display panel module of the plasma display apparatus according to the first embodiment;

FIG. 5 is a cross-sectional view of the plasma display panel module of the plasma display apparatus according to the first embodiment as taken in the width direction thereof;

FIG. 6 is a cross-sectional view of the plasma display panel module of the plasma display apparatus according to the first embodiment as taken in the longitudinal direction thereof;

FIG. 7 is a perspective view showing the entirety of the plasma display panel module of a plasma display apparatus according to a second embodiment;

FIG. 8 is a cross-sectional view of a plasma display panel module of the plasma display apparatus according to a third embodiment as taken in the width direction;

FIG. 9 is an exploded, perspective view of the entirety of the plasma display panel module of the plasma display apparatus according to the third embodiment; and

FIG. 10 is a cross-sectional view of a plasma display panel module of a related-art plasma display apparatus.

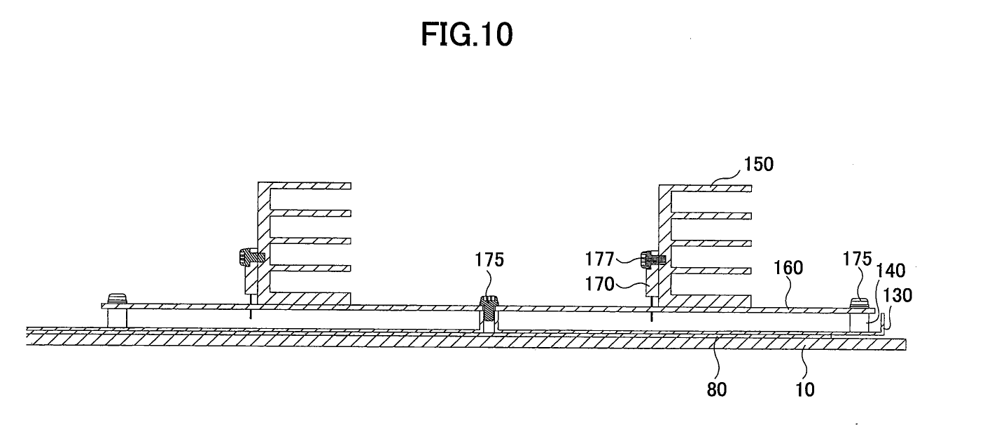

### DESCRIPTION OF THE PREFERRED EMBODIMENTS

In the following, the best mode for carrying out the present invention will be described in detail by referring to the accompanying drawings.

### First Embodiment

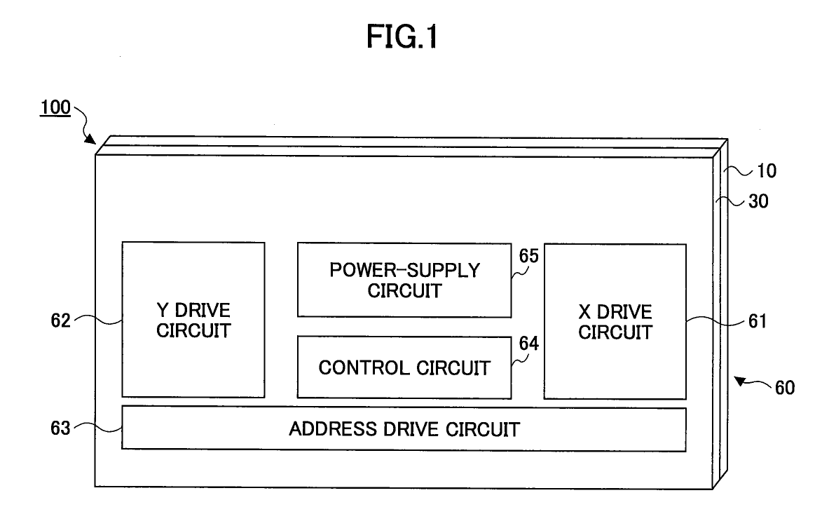

FIG. 1 is a drawing showing a schematic configuration of a plasma display panel module of a plasma display apparatus according to a first embodiment. In FIG. 1, a plasma display panel module 100 mainly includes a plasma display panel 10 serving as a display unit on a front side and a chassis 30 disposed on a back side to fixedly support the plasma display panel 10.

In the following embodiments for which a description will be given of the plasma display panel module 100 of the plasma display apparatus, the plasma display panel module 100 may include other components such as signal processing circuits in addition to those components explicitly described as provided on the plasma display panel module 100.

The plasma display panel module 100 is assembled at the time of product assembly by fixedly attaching the plasma display panel 10 to the chassis 30 through an adhesive layer (e.g., plural pieces of double-faced adhesive tape). The plasma display panel module 100 is then assembled with an exterior case and the like to constitute a plasma display apparatus (final product) of this embodiment.

The plasma display panel 10 and the chassis 30 are each a structural member having substantially a rectangle, flat plate shape A circuit board 60 having circuits (drive circuits) thereon for driving the plasma display panel 10 is disposed and supported on the back face of the chassis 30. The circuit board 60 includes an X (sustain) drive circuit board 61, a Y (scan) drive circuit board 62, an address drive circuit board 63, a control circuit board 64, and a power-supply circuit board 65.

The power-supply circuit board 65 serves to supply an electric power to the circuit boards 61, 62, 63, and 64. The control circuit board 64 serves to control the entirety of the plasma display apparatus, and is connected to the circuit board 61, 62, and 63. The control circuit board 64 generates and outputs drive control signals based on a display signal, a control clock, and the like. The drive circuits on the drive circuit boards 61, 62, and 63 are electrically connected to corresponding electrode sets provided in the plasma display panel 10. An X drive circuit on the X drive circuit board 61 applies a drive voltage to X electrodes. A Y drive circuit on the Y drive circuit board 62 applies a drive voltage to Y electrodes. An address drive circuit on the address drive circuit board 63 applies a drive voltage to address electrodes.

The address drive circuit board 63 serves to supply, to each address driver (not shown), drive control signals derived from the signals generated by the control circuit board 64. Components provided on the address drive circuit board 63 are mainly directed to maintaining a stable operation. Direct and individual driving of an address electrode set of the plasma display panel 10 is performed by a driver IC (not shown) implemented in each address driver. Each address driver uses the driver IC to drive the address electrode set in response to the drive control signals supplied from the address drive circuit board 63 in order to cause the luminescent cells of the plasma display panel 10 to emit light. Namely, the driver IC generates drive signals (voltage waveforms) for driving (address driving) the corresponding address electrodes of the plasma display panel 10 in accordance with the drive control signals supplied from the address drive circuit board 63. The generated drive signals are applied to the corresponding address electrodes via signal lines. In the address driving operation, voltages applied to the address electrodes and Y electrodes generate electric discharge for selecting the luminescent cells that are to emit light.

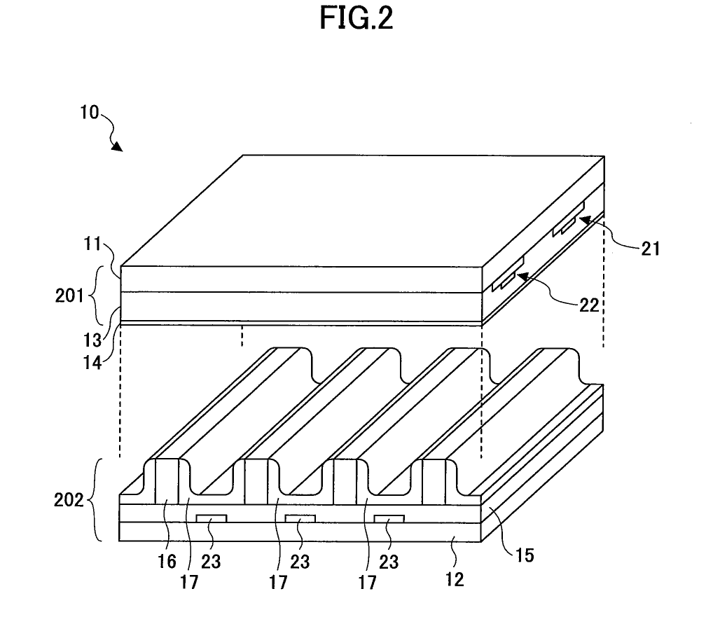

In the following, an example of the configuration of the plasma display panel 10 will be described with reference to FIG. 2. FIG. 2 is a drawing showing an example of the configuration of the plasma display panel 10 of the plasma display apparatus according to the first embodiment. The plasma display panel 10 is assembled by attaching a front unit 201 including a front panel 11 mainly comprised of glass to a rear unit 202 including a back panel 12.

The front panel 11 of the front unit 201 includes a plurality of X (sustain) electrodes 21 and Y (scan) electrodes 22 for performing consecutive display discharges (sustain discharges) that are alternately arranged in parallel to extend in a first (horizontal) direction. The X electrodes 21 and the Y electrodes 22 serving as display electrodes are covered with a first dielectric layer 13, the surface of which is in turn covered with a protective layer 14 made of magnesium oxide or the like. Each of the X electrodes 21 and the Y electrodes 22 is comprised of a bus electrode made of metal having a straight line shape and a transparent electrode electrically connected to the bus electrode to generate discharge.

The back panel 12 of the front unit 201 includes a plurality of address electrodes 23 arranged in parallel to extend in a second (vertical) direction substantially perpendicular to the X electrodes 21 and the Y electrodes 22. The address electrodes 23 are covered with a second dielectric layer 15. On both sides of each of the address electrodes 23 are provided barrier ribs 16 extending in the second direction, which define columns and display cells in the display area of the plasma display panel 10. Further, a phosphor layer 17 for generating each of red (R), green (G), and blue (B) visible light upon excitation by ultraviolet light is formed for each color on the second dielectric layer 15 covering the address electrodes 23 and on the lateral faces of the barrier ribs 16. A pair of an X electrode 21 and a Y electrode 22 forms each display line (row). The display lines and the address electrodes 23 intersect each other to form a display cell corresponding to the area defined by the barrier ribs 16. A matrix of such display cells constitutes the display area of the plasma display panel 10.

The front panel 11 and the back panel 12 are attached to each other such that the protective layer 14 is in contact with the top face of the barrier ribs 16. A discharge gas such as Ne, Xe, or the like is then injected to fill the inside space of the plasma display panel 10. Each electrode set of the plasma display panel 10 extends up to the edge portion of the plasma display panel 10 outside its sealed area to be connected to the drive circuits provided on the back face of the chassis 30 via a flexible printed-circuit board of the driver module.

In the following, a description will be given of a method of fixedly supporting the circuit board 60 by the chassis 30 in the plasma display apparatus of the present embodiment having the plasma display panel module 100 as described above.

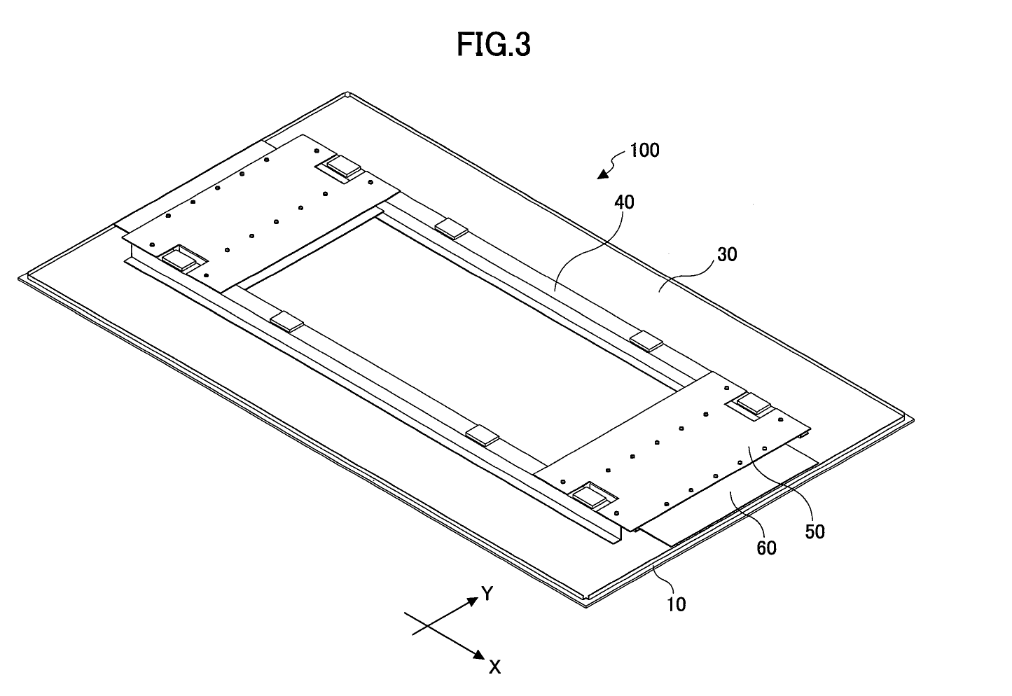

FIG. 3 is a perspective view showing the entirety of the plasma display panel module 100 of the plasma display apparatus according to the first embodiment. FIG. 3 shows a view of the back side of the chassis 30. As shown in FIG. 3, the plasma display panel 10 is fixedly attached to a face (front face) of the chassis 30. The other face (back face) of the chassis 30 has reinforcing members 40, a heat sink 50, and the circuit board 60 disposed thereon.

The chassis 30 serves to securely support the plasma display panel 10 on one surface thereof, and also serves to securely support the circuit board on the other surface thereof for driving the plasma display panel 10. The chassis 30 may be made of a metal having a high thermal conductivity such as iron or aluminum in order to dissipate heat generated by the plasma display panel 10.

The reinforcing members 40 serve to reinforce the structural integrity of the plasma display panel 10 via the chassis 30. In FIG. 3, the reinforcing members 40 are disposed on the back face of the chassis 30 to bulge from the flat surface of the chassis 30, and form two lines extending substantially in parallel. The reinforcing members 40 serve as a brace for supporting and reinforcing the chassis 30 and the plasma display panel 10 from behind. Accordingly, it is preferable to implement the reinforcing members 40 by use of a simple structure that is sturdy and light. As shown in FIG. 3, for example, a long and thin plate-shape member may be bent to form a hollow square prism with the face of the chassis 30 upon being attached to the chassis 30, thereby reinforcing the rigidity of the chassis 30 and the plasma display panel 10.

The reinforcing members 40 need to serve as a platform on which the heat sink 50 is fixedly mounted as shown in FIG. 3, so that the reinforcing members 40 are spaced apart and opposed to each other (i.e., extend alongside each other). Since the reinforcing members 40 can properly serve as a platform as long as they are arranged to oppose each other, various arrangements may be possible. From the viewpoint of mounting the heat sink 50 uniformly at plural supporting points, the reinforcing members 40 are preferably arranged to extend substantially in parallel to be opposed to each other (like the opposite sides of a rectangle).

As shown in FIG. 3, the reinforcing members 40 may be comprised of a plurality of reinforcing members each extending in a straight line and arranged substantially in parallel to be opposed to each other at a predetermined interval. The reinforcing members 40 may alternatively be implemented as a single piece having opposite sides, which may be an H-letter shape or rectangular shape, for example.

The reinforcing members 40 are preferably made of a material that has a high thermal conductivity for the purpose of transmitting heat to the chassis 30, that is relatively easy to process, and that has a certain degree of rigidity. For example, a metal plate such as an iron plate or aluminum plate may be used, as in the case of the chassis 30.

The reinforcing members 40 may be made as an integral unitary structure together with the chassis 30, or may be made as separate parts, which are then fixedly attached to the chassis 30 having a flat-plate shape. In the example shown in FIG. 3, the chassis 30 and the reinforcing members 40 are manufactured as separate parts, and, then, the reinforcing members 40 are fixedly attached to the chassis 30.

The heat sink 50 serves to dissipate heat that is transmitted from the circuit board 60 and heat that is transmitted from the chassis 30 through the reinforcing members 40. The heat sink 50 according to the present embodiment is fixedly mounted in such a manner to bridge between the reinforcing members 40 that are opposed to each other. The heat sink 50 thus has a width wider than the gap between the reinforcing members 40. The shape of the heat sink 50 may properly be selected from various shapes including an arc shape or an L shape as long as it has a sufficiently broad area size that allows bridging between the reinforcing members 40. Nonetheless, it may be preferable to use the heat sink 50 having a flat-plate shape from the viewpoint of forming a thin plasma display panel module 100 and also from the viewpoint of securely supporting the circuit board 60. In FIG. 3, the heat sink 50 is configured as a flat heat sink plate.

The heat sink 50 may preferably be formed of a material having a high thermal conductivity, and may be implemented by use of an iron plate or aluminum plate, for example.

As previously described, the circuit board 60 is a circuit board carrying circuits for driving the plasma display panel 10. The circuit board 60 may include the X drive circuit board 61, the Y drive circuit board 62, the address drive circuit board 63, the control circuit board 64, and the power-supply circuit board 65. Among these, the X drive circuit board 61, the Y drive circuit board 62, and the power-supply circuit board 65 are particularly suited for use in the plasma display panel module 100 of the plasma display apparatus according to this embodiment. The circuit board 60 operates when driving the plasma display panel 10. Since heat source devices such as FETs are used as components, a large amount of heat is generated, thereby creating a risk that the circuit board 60 may be distorted due to the generated heat. In the plasma display apparatus according to the present embodiment, the heat sink 50 supports the circuit board 60 to separate the circuit board 60 from the chassis 30, thereby preventing the distortion of the circuit board 60 from affecting the plasma display panel 10. The detailed configuration will be described later.

The circuit board 60 may be made of a material selected from various choices, and may properly be made of a resin such as a glass epoxy resin. As described above, provision is made such that a distortion of the circuit board 60, if occurs, would not propagate as a stress to the plasma display panel 10. There is thus no need to take into account tolerance against thermal distortion, which means that various materials can be used for the circuit board 60 according to application.

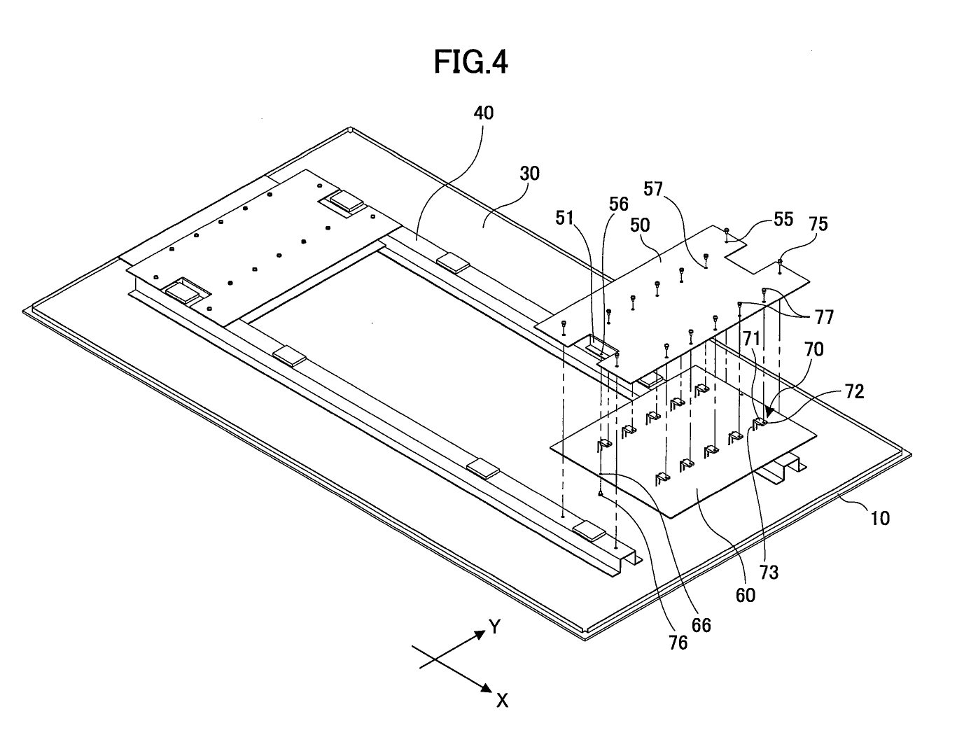

FIG. 4 is an exploded, perspective view of the entirety of the plasma display panel module 100 of the plasma display apparatus according to the first embodiment. Structural members illustrated in FIG. 4 are the same as those described in connection with FIG. 3. In FIG. 4, however, some structural members that were not shown in the view of the finished product of FIG. 3 are additionally illustrated.

In FIG. 4, the reinforcing members 40 bulge from the surface of the chassis 30 as two rails extending in parallel, each forming a hollow cross-section that has a rectangular shape. A long and thin metal plate may be bent into a proper shape, which is then adhesively attached to the surface of the chassis 30, for example, thereby forming the bulging structure shown in FIG. 4 that extends straight.

The reinforcing members 40 may not have to form a rectangular cross section, and may properly bulge as an arc shape member or as an L-shape member having a triangular cross section. Since the heat sink 50 is fixedly mounted on the top of the reinforcing members 40, however, the top is preferably formed as a flat face in order to secure a large contact area size between the reinforcing members 40 and the heat sink 50. In FIG. 4, the reinforcing members 40 are configured as having a flat surface on the top. Such configuration ensures that the heat sink 50 is securely fixed to the reinforcing members 40. Although the example shown in FIG. 4 employs the reinforcing members 40 having a rectangular-shape cross-section, a cross-section may be configured to have a trapezoid shape. Such shape also has a flat surface at the top, so that secure mounting can also be achieved. Any one of the various shapes described here may properly be employed as the shape of the reinforcing members 40.

The heat sink 50 has screw holes 55 at positions corresponding to the positions of the reinforcing members 40, and is threadably mounted to the reinforcing members 40 by screws 75. The mounting of the heat sink 50 to the reinforcing members 40 may be achieved by use of some other method such as the use of an adhesive agent or a double-faced adhesive tape, and may properly be performed by use of any method selected from various choices. The example shown in FIG. 4 is directed to a configuration in which the heat sink 50 is securely fixed to the reinforcing members 40 by use of a simple means, i.e., the screws 75.

The heat sink 50 includes a top face serving as a heat dissipating plate, and also includes a board supporting part 51 extending in a vertical direction to support the circuit board 60. The tip of the board supporting part 51 forms a horizontal plate part for supporting the circuit board 60. The horizontal plate part has a screw hole 56, which is used to fixedly mount the circuit board 60 by use of a screw 76. The board supporting part 51 has a vertical length that is shorter than the elevation of the reinforcing members 40 when the circuit board 60 is held under the heat sink 50, i.e., between the heat sink 50 and the chassis 30. This is because the vertical length (extension in the normal direction) of the board supporting part 51 needs to be shorter than the elevation of the reinforcing members 40 in order to hold the circuit board 60 between the chassis 30 and the heat sink 50 in such a position that the circuit board 60 is not in direct contact with the chassis 30. It is possible to employ a configuration in which the circuit board 60 is held over the heat sink 50 rather than between the heat sink 50 and the chassis 30. Such a configuration can also prevent a stress from propagating to the plasma display panel 10, but causes an increase in the thickness of the plasma display panel module 100. Because of this, the board supporting part 51 preferably extends downward from the top surface of the heat sink 50.

The mounting of the circuit board 60 to the board supporting part 51 may be performed by use of some other means such as an adhesive agent or a double-faced adhesive tape instead of using screws.

The flat plate portion of the heat sink 50 serving as a heat dissipating surface has screw holes 57, which are used to fix heat source devices 70 of the circuit board 60 by use of screws 77. The screw holes 57 may be formed as many as necessary at positions corresponding to the positions of the heat source devices 70 on the circuit board 60 so as to allow the mounting of the heat source devices 70 through the screws 77.

Since the circuit board 60 is held in such position between the reinforcing members 40 that the circuit board 60 is supported at its side edges, the width (length in the Y direction) of the circuit board 60 is configured to be shorter than the interval of the opposed reinforcing members 40. Such dimension may be determined by taking into account the relative positions of the circuit board 60 and the reinforcing members 40. The lengthwise dimension (i.e., length in the X direction) of the circuit board 60 in the direction in which the reinforcing members 40 extend may be set to any desired value as long as it does not exceeds the length of the reinforcing members 40.

The circuit board 60 has a screw hole 66 at a position corresponding to the position of the horizontal plate part of the board supporting part 51 of the heat sink 50, so that the circuit board 60 is fixedly mounted to the board supporting part 51 by use of a screw.

The heat source devices 70 such as FETs are mounted on the surface of the circuit board 60. In order to achieve efficient heat dissipation from the heat source devices 70, device cores 71 of the heat source devices 70 may have screw holes 72, which allow mounting to the heat sink 50. The heat source devices 70 are held in direct contact with the heat sink 50 having a heat dissipating area extending in the horizontal direction. In consideration of this, leads 73 of the heat source devices 70 may be bent to extend in the horizontal direction in order to position the heat source devices 70 to have a heat dissipation area extending in the horizontal direction. Such positioning makes it possible to secure a large contact area between the heat source devices 70 and the heat sink 50, thereby increasing the heat dissipation efficiency of the heat source devices 70.

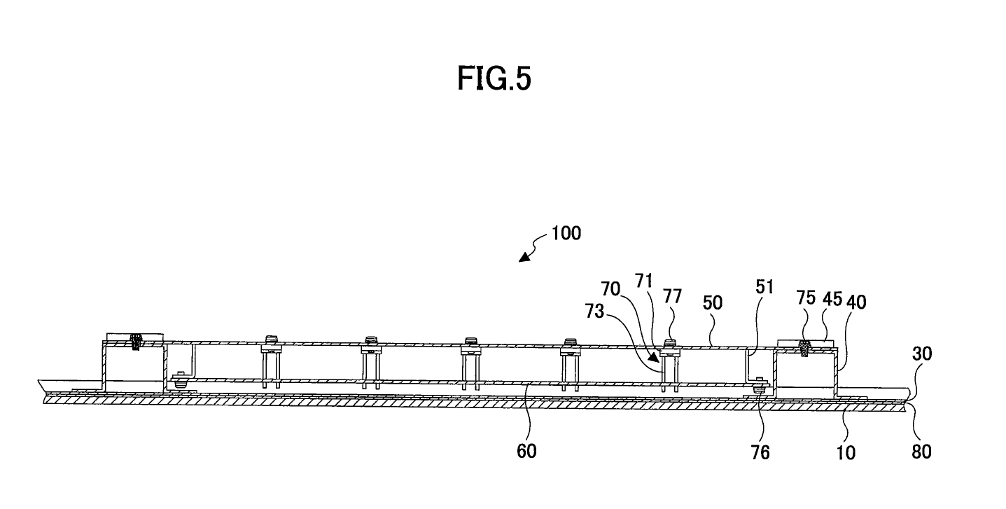

FIG. 5 is a cross-sectional view of the plasma display panel module 100 of the plasma display apparatus according to the first embodiment as taken in a width direction (in the Y direction shown in FIG. 3). Structural members illustrated in FIG. 5 are the same as those described heretofore, and a description thereof will be omitted. The following description will be given with respect to the arrangements of these members.

In FIG. 5, the plasma display panel 10 is attached through the adhesive layer 80 to the front face (i.e., lower surface as appear in FIG. 5) of the chassis 30. On the back face (i.e., upper surface as appear in FIG. 5) of the chassis 30 are provided the reinforcing members 40 extending in parallel to each other and having a cross-sectional view as shown on either side in FIG. 5. It can be clearly seen that the reinforcing members 40 serve as a prism bulging in a rectangular shape.

The top faces of the reinforcing members 40 opposed to each other support the heat sink 50 bridging therebetween. The screws 75 are used to fixedly mount the heat sink 50 to the reinforcing members 40. An area surrounding each screw 75 may be covered with a resin member 45 such as plastic.

As shown in FIG. 5, the heat sink 50 has a width wider than the gap between the opposing reinforcing members 40 so that a wide heat dissipation area size can be provided. With this provision, the heat dissipation ability of the plasma display panel module 100 can be improved.

The heat sink 50 has the board supporting part 51 extending downwards and having an L-shape cross-section at each of the side edges thereof at a position between the opposing reinforcing members 40. The horizontal plate part provided at the lower end of the board supporting part 51 is in contact with a side edge part of the circuit board 60, and the screw 76 is used to fixedly mount the circuit board 60.

The circuit board 60 has no direct contact with the inside walls of the reinforcing members 40 situated at some horizontal distance from the circuit board 60, and has no direct contact with the chassis 30 situated under the circuit board 60. The circuit board 60 is supported by and in direct contact with only the board supporting parts 51. Such arrangement ensures that a distortion of the circuit board 60 caused by heat does not propagate as a stress to the chassis 30, thereby preventing a thermal distortion stress from being applied to the plasma display panel 10.

It should be noted that the circuit board 60 is accommodated in the space defined by the heat sink 50 situated above, the reinforcing members 40 situated alongside, and the chassis 30 situated below. Because of this, the width of the circuit board 60 should be narrower than the interval of the reinforcing members 40, and the sum of the vertical length of the board supporting part 51, the thickness of the bottom plate part of the board supporting part 51, the thickness of the circuit board 60, and the length of the head of the screw 76 is smaller that the elevation of the reinforcing members 40. If the elevation of the reinforcing members 40 is 20 mm, for example, the above-noted sum is configured to be smaller than 20 mm.

Various circuit components are mounted on the upper surface of the circuit board 60 to constitute predetermined circuits. The heat source devices 70, whose heat generation is particularly conspicuous among these circuit components, are fixedly attached to the heat sink 50 by the screws 77, thereby helping to dissipate heat from the top of the heat sink 50. The heat source devices 70 may be FETs, for example. The device cores 71 of the heat source devices 70 are fixedly attached to the heat sink 50 to have direct contact therewith as shown in FIG. 5, thereby reliably transmitting heat to the reinforcing members 40.

The heat sink 50 holds the circuit board 60 having a flat shape. For the purpose of fixedly attaching the heat source devices 70 mounted at various positions across the circuit board 60, the shape of the heat sink 50 is preferably the same flat shape as the circuit board 60.

With the arrangement shown in FIG. 5, the efficiency of heat dissipation is improved, and the effect of distortion of the circuit board 60 is minimized, while achieving a thin plasma display panel module 100.

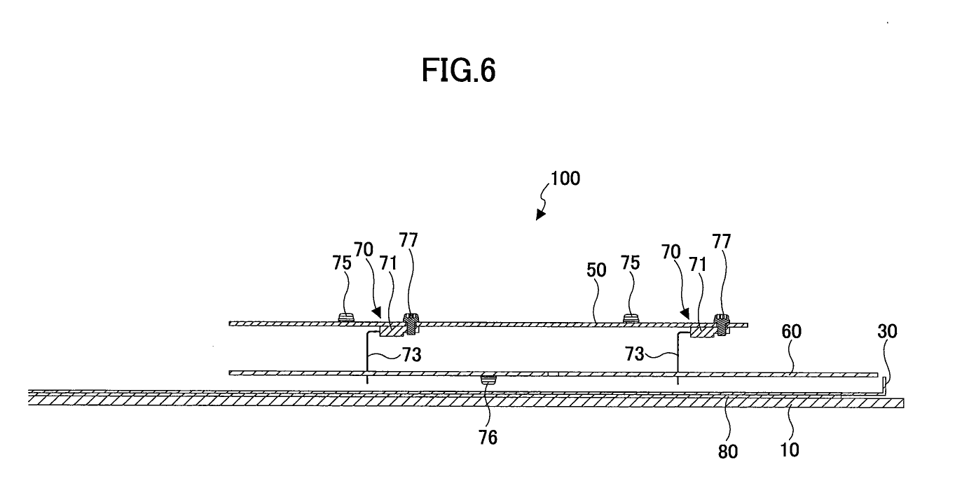

FIG. 6 is a cross-sectional view of the plasma display panel module 100 of the plasma display apparatus according to the first embodiment as taken in a longitudinal direction (in the X direction shown in FIGS. 3 and 4).

As shown in FIG. 6, the plasma display panel 10 is fixedly attached to a front face (i.e., the lower surface as appear in FIG. 6) of the chassis 30 through the adhesive layer 80 such as a double-faced adhesive tape. Also, the circuit board 60 and the heat sink 50 are mounted to a back face (i.e., the upper surface as appear in FIG. 6) of the chassis 30. Although the illustration of the reinforcing members 40 is omitted in FIG. 6, the heat sink 50 is fixedly mounted to the reinforcing members 40 by use of the screws 75. Although not illustrated, also, the circuit board 60 is fixedly mounted to the heat sink 50 by the screws 76. The heat source devices 70 are mounted on the circuit board 60 through soldering or the like, and the device cores 71 of the heat source devices 70 are fixedly attached to the heat sink 50 by use of the screws 77. It is preferable for the largest surface of the device cores 71 of the heat source devices 70 to be in direct contact with the heat sink 50 to provide a large surface area for heat dissipation. Accordingly, the plasma display panel module 100 of the plasma display apparatus of the present embodiment is configured such that the leads 73 are bent substantially at a right angle to place the device cores 71 in horizontal position. With this arrangement, a large heat dissipation area extending in the horizontal direction is provided when the device cores 71 are fixedly attached to the heat sink 50.

In this manner as shown in FIG. 6, the mounting method employed in this embodiment is well devised in order to secure a large contact area between the heat source devices 70 mounted on the circuit board 60 and the heat sink 50 placed in horizontal position.

As described heretofore with reference to FIG. 1 through FIG. 6, the plasma display apparatus of the first embodiment is configured such that the plasma display panel module 100 is achieved as a thin module while improving heat dissipation efficiency and reducing a risk of causing a defect (crack) in the plasma display panel 10.

### Second Embodiment

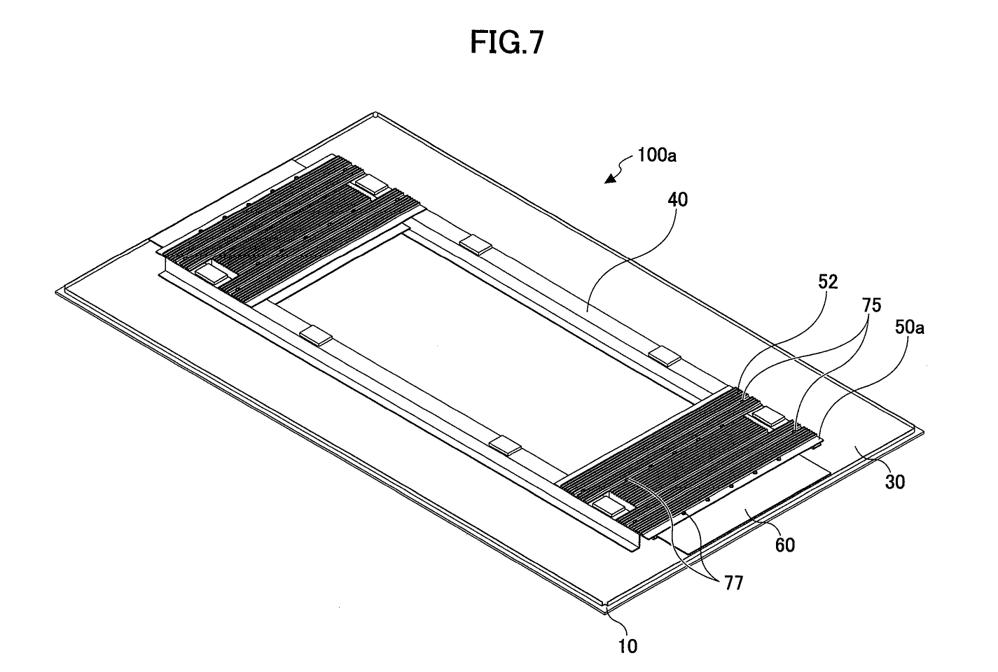

FIG. 7 is a perspective view showing the entirety of a plasma display panel module 100a of the plasma display apparatus according to the second embodiment. In the plasma display apparatus of the second embodiment, the configurations of the plasma display panel 10 and the circuit board 60 are the same as those of the plasma display apparatus of the first embodiment described in connection with FIG. 1 and FIG. 2, and a description thereof will be omitted.

In FIG. 7, the plasma display panel module 100a of the plasma display apparatus according to the second embodiment has the plasma display panel 10 fixedly attached to the front face (i.e., the lower surface as appear in FIG. 7) of the chassis 30. The reinforcing members 40 extending substantially in parallel to each other are disposed on the back face (i.e., the upper surface as appear in FIG. 7) of the chassis 30. A heat sink 50a is fixedly mounted to the reinforcing members 40 by the screws 75 to bridge therebetween. The circuit board 60 is fixedly attached to the heat sink 50a. Further, the heat source devices 70 (not shown in FIG. 7) mounted on the circuit board 60 are fixedly attached to the heat sink 50a by the screws 77. As far as these arrangements are concerned, the plasma display panel module 100a of the plasma display apparatus according to the second embodiment is the same as the plasma display panel module 100 of the plasma display apparatus according to the first embodiment.

The plasma display panel module 10a of the plasma display apparatus according to the second embodiment differs from the plasma display panel module 100 of the plasma display apparatus according to the first embodiment in that cooling fins 52 are disposed on the surface of the heat sink 50a. In this manner, the cooling fins 52 may be provided on the surface of the heat sink 50a. The use of the heat sink 50a having the cooling fins 52 disposed thereon can improve the efficiency of heat dissipation by the heat sink 50a.

Cooling fins having various shapes may be used as the cooling fins 52. When the plasma display panel module 10a is to be implemented as a thin module, the cooling fins 52 may be implemented as fine, short fins having a small elevation from the surface of the heat sink 50a as shown in FIG. 7.

According to the plasma display apparatus of the second embodiment, the cooling fins 52 are disposed on the large surface area of the heat sink 50a. With this arrangement, the efficiency of heat dissipation can be further improved while implementing the plasma display panel module 100a as a thin module as in the first embodiment.

### Third Embodiment

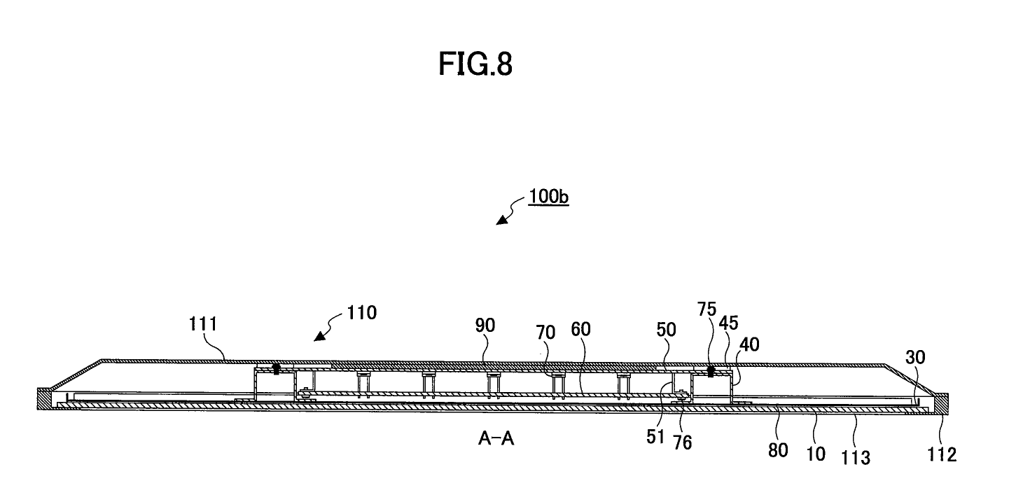

FIG. 8 is a cross-sectional view of a plasma display panel module 100b of the plasma display apparatus according to a third embodiment as taken in a width direction. In the plasma display apparatus of the third embodiment, the configurations of the plasma display panel 10 and the circuit board 60 are the same as those of the plasma display apparatus of the first embodiment described in connection with FIG. 1 and FIG. 2, and a description thereof will be omitted.

In FIG. 8, the plasma display panel module 100b of the plasma display apparatus according to the third embodiment differs from the plasma display panel modules 100 and 100a of the plasma display apparatus according to the first and second embodiment in that a cooling mechanism is implemented together with a case 110 for accommodating the plasma display panel 10 and the chassis 30.

In FIG. 8, the plasma display panel module 100b of the plasma display apparatus according to the third embodiment has the plasma display panel 10 fixedly attached through the adhesive layer 80 to the front face (i.e., the lower surface as appear in FIG. 8) of the chassis 30. FIG. 8 also illustrates a front cover 112 and front filter 113 covering the front face of the plasma display panel 10. Although these elements were not described in the first and second embodiments, they may be provided similarly in the first and second embodiments.

In FIG. 8, the opposing reinforcing members 40 are disposed on the back face (i.e., the upper surface as appear in FIG. 8) of the chassis 30. The heat sink 50 is disposed to bridge between the reinforcing members 40, and is fixedly mounted to the reinforcing members 40 by the screws 75. An area surrounding each screw 75 may be covered with a resin member 45. The heat sink 50 has the board supporting part 51 extending downwards and having an L shape. The bottom horizontal plate part of the board supporting part 51 has the circuit board 60 fixedly attached thereto by the circuit board 60. The heat source devices 70 mounted on the circuit board 60 are fixedly attached to the heat sink 50.

The configurations described above are the same as those of the plasma display panel modules 100 and 100a of the plasma display apparatus of the first and second embodiments. The plasma display panel module 100b of the plasma display apparatus of the third embodiment differs from the plasma display panel modules 100 and 100a of the plasma display apparatus of the first and second embodiments in that a rear cover 111 of the case 110 covers the entire back face of the chassis 30, and in that a thermal conduction sheet 90 is inserted between the rear cover 111 and the heat sink 50.

With this arrangement, the heat transmitted to the heat sink 50 can be transmitted to the rear cover 111 through the thermal conduction sheet 90, thereby helping to dissipate the heat to outside the case 110. With such a configuration in which the case 110 of the plasma display panel module 100b is implemented as a thin case, and the thermal conduction sheet 90 is placed at a narrow gap between the rear cover 111 and the heat sink 50 to provide a heat transmitting contact, the heat transmitted to the heat sink 50 can be dissipated to outside the case 110 via the thermal conduction sheet 90, without being trapped inside the case 110.

The thermal conduction sheet 90 may be formed in a sheet-like shape by use of a material such as silicon, or may be made of some other material having a high thermal conductivity and some degree of flexibility. The rear cover 111 of the case 110 may be made of resin, or may be made of metal such as aluminum or iron.

The heat sink 50, the thermal conduction sheet 90, and the rear cover 111 of the case 110 may be adhesively attached together by use of an adhesive agent or a double-faced adhesive tape. Alternatively, the thermal conduction sheet 90 is held steady by being clamped between the heat sink 50 and the rear cover 111. With this arrangement in which the rear cover 111 of the case 110 is made to have a minimum thickness required to cover the heat sink 50, and the thermal conduction sheet 90 is placed between the rear cover 111 and the heat sink 50, the plasma display panel module 100b can be implemented as a thin module that has a high heat dissipation efficiency to allow the heat generated inside the case 110 to be dissipated to outside the case 110.

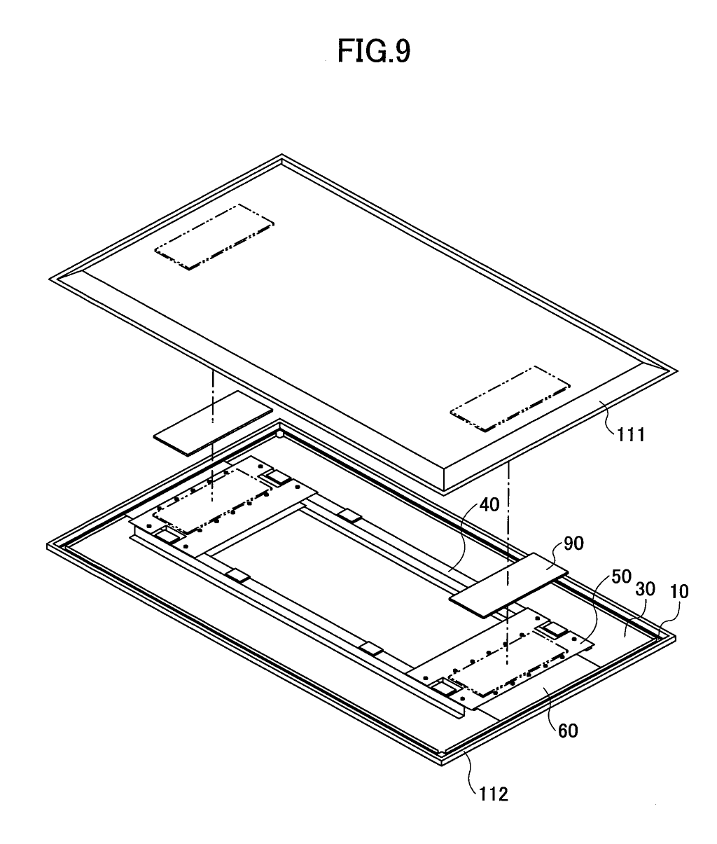

FIG. 9 is an exploded, perspective view of the entirety of the plasma display panel module 100b of the plasma display apparatus according to the third embodiment.

In FIG. 9, like the configuration described heretofore, the plasma display panel 10 is fixedly attached to the front face of the chassis 30, and the front cover 112 of the case 110 covers the front face of the plasma display panel 10. The back face of the chassis 30 has the reinforcing members 40 extending alongside. The heat sink 50 is fixedly mounted on the reinforcing members 40 to bridge therebetween, and the circuit board 60 is supported under the heat sink 50.

The thermal conduction sheet 90 is placed on the surface of the heat sink 50. The plasma display panel module 100b of the plasma display apparatus of the third embodiment may be assembled by placing the rear cover 111 of the case 110 from above to cover the thermal conduction sheet 90.

In this manner, the plasma display panel module 100b of the plasma display apparatus of the third embodiment can be implemented through a simple assembling process as a thin module having a high thermal efficiency.

According to the plasma display apparatus of the third embodiment, a thin plasma display panel module 100b can be implemented while reducing a risk of creating a defect in the plasma display panel 10 and efficiently dissipating heat from inside the case 110 to outside the case 110.

Further, the present invention is not limited to these embodiments, but various variations and modifications may be made without departing from the scope of the present invention.

The present application is based on Japanese priority application No. 2007-338007 filed on Dec. 27, 2007, with the Japanese Patent Office, the entire contents of which are hereby incorporated by reference.

What is claimed is:

1. A plasma display apparatus, comprising:
a plasma display panel;
a chassis having the plasma display panel fixedly mounted on one face thereof, and having reinforcing members disposed as bulges on another face thereof to extend alongside each other;
a heat sink fixedly mounted on the reinforcing members extending alongside each other to bridge between the reinforcing members; and
a circuit board fixedly mounted on the heat sink to drive the plasma display panel.

2. The plasma display apparatus as claimed in claim 1, wherein the circuit board is situated between the heat sink and the chassis.

3. The plasma display apparatus as claimed in claim 1, wherein the heat sink is a flat heat dissipating plate.

4. The plasma display apparatus as claimed in claim 1, wherein the reinforcing members are reinforcing metal parts each having a flat face at an elevated top.

5. The plasma display apparatus as claimed in claim 1, wherein the heat sink has cooling fins provided on a surface thereof.

6. The plasma display apparatus as claimed in claim 3, further comprising
a rear cover configured to cover said another face of the chassis; and
a thermal conduction sheet placed between the rear cover and the heat sink.

7. The plasma display apparatus as claimed in claim 1, wherein the circuit board has a heat source device mounted thereon, which is fixedly attached to the heat sink.

8. The plasma display apparatus as claimed in claim 7, wherein the heat source device has a lead that is bent, the heat source device being laid in horizontal position to be fixedly attached to the heat sink.

9. The plasma display apparatus as claimed in claim 8, wherein the heat source device is a field effect transistor.

10. The plasma display apparatus as claimed in claim 1, wherein the circuit board includes at least one of an X drive circuit board and a Y drive circuit board.

11. The plasma display apparatus as claimed in claim 1, wherein the circuit board includes a power-supply circuit board.
